(19) United States
(12) Patent Application Publication
(10) Pub. No.: US 2016/0195970 A1
(43) Pub. Date: Jul. 7, 2016

(54) TOUCH SCREEN PANEL AND METHOD OF MANUFACTURING THE SAME

(71) Applicant: SAMSUNG DISPLAY CO., LTD., Yongin-si (KR)

(72) Inventors: Jong-Hyun CHOI, Yongin-si (KR); Seung-Rok LEE, Yongin-si (KR)

(21) Appl. No.: 14/834,651

(22) Filed: Aug. 25, 2015

(30) Foreign Application Priority Data
Jan. 6, 2015 (KR) 10-2015-0001387

(51) Int. Cl. G06F 3/041; G06F 1/16; H05K 3/12; H05K 1/09; H05K 3/00; G06F 3/044; H05K 1/02

(52) U.S. Cl. CPC G06F 3/0412; G06F 3/044; G06F 1/16; H05K 1/0296; H05K 1/092; H05K 3/0094; H05K 3/12; G06F 2203/04103

(57) ABSTRACT

A touch screen panel includes a substrate including a touch active area and a touch non-active area, the touch non-active area being defined at an outer portion of the touch active area, lines located in the touch non-active area of the substrate, each of the lines including a metal layer including a nano structure and a transparent conductive oxide layer on the metal layer, a passivation layer covering parts of the lines such that distal ends of the lines are exposed, and pads electrically connected with the distal ends of the lines.

### CROSS-REFERENCE TO RELATED APPLICATION

Korean Patent Application No. 10-2015-0001387, filed on Jan. 6, 2015, in the Korean Intellectual Property Office, and entitled: “Touch Screen Panel and Method of Manufacturing the Same,” is incorporated by reference herein in its entirety.

### BACKGROUND

1. Field

Embodiments relate to a touch screen panel and a method of manufacturing the same.

2. Description of the Related Art

A touch screen panel is an input device that allows a user to input a command by selecting indication contents shown on a screen of an image display device, or the like by using a finger or an object.

To this end, the touch screen panel is provided on a front surface of the image display device. The touch screen panel converts a contact position, with which the hand of the person or the object is in direct contact, into an electrical signal. Accordingly, indication contents selected at the contact position are received as an input signal.

The touch screen panel may replace a separate input device, such as a keyboard or a mouse, which operate while being connected to an image display device. Accordingly, use of a touch screen panel has gradually increased.

### SUMMARY

Embodiments are directed to a touch screen panel including a substrate including a touch active area and a touch non-active area. the touch non-active area being defined at an outer portion of the touch active area, lines located in the touch non-active area of the substrate, each of the lines including a metal layer including a nano structure and a transparent conductive oxide layer on the metal layer, a passivation layer covering parts of the lines such that distal ends of the lines are exposed, and pads electrically connected with the distal ends of the lines.

The pads may partially cover the passivation layer.

The passivation layer may include one or more through-holes that expose the lines. The pads may be electrically connected with the lines through the one or more through-holes.

Each of the pads may have a larger width than a respective one of the lines.

Each of the pads may be in contact with an upper surface and a lateral wall of the respective one of the lines.

The touch screen panel may further include sensing electrodes located in the touch active area of the substrate, the sensing electrodes being connected with the lines.

Each of the sensing electrodes may include a metal layer including a nano structure and a transparent conductive oxide layer on the metal layer.

The touch non-active area may include a first touch non-active area defined at the outer portion of the touch active area, the lines being located in the first touch non-active area, and a second touch non-active area defined at an outer portion of the first touch non-active area, the pads being arranged in the second touch non-active area.

The passivation layer may be located in the touch active area and the first touch non-active area.

The passivation layer may be located in the first touch non-active area.

The metal layer may include a nano wire, a nano tube, or a nano rod structure.

Each of the pads may include silver (Ag), palladium (Pd), or platinum (Pt).

Embodiments are also directed to a method of manufacturing a touch screen panel including forming lines including a metal layer having a nano structure and a transparent conductive oxide layer on the metal layer, on a substrate, forming a passivation layer covering parts of the lines such that distal ends of the line are exposed; and forming pads electrically connected with the distal ends of the lines.

Forming the pads may include applying a metal paste to be in contact with the lines, and forming the pads by printing the metal paste.

Each of the pads may be formed to partially cover the passivation layer.

The method may further include, before forming the pads, forming one or more through-holes that pass through the passivation layer and expose the lines.

Forming the pads may include applying a metal paste so as to fill the one or more through-holes and be in contact with the lines, and forming the pads by printing the metal paste.

The substrate may include a touch active area, a first touch non-active area that is defined at the outer portion of the touch active area and in which the lines are arranged, and a second touch non-active area that is defined at an outer portion of the first touch non-active area and in which the pads are arranged.

The passivation layer may cover regions of the lines corresponding to the first touch non-active area, and may expose regions of the lines corresponding to the second touch non-active area.

### BRIEF DESCRIPTION OF THE DRAWINGS

Features will become apparent to those of skill in the art by describing in detail exemplary embodiments with reference to the attached drawings in which:

FIG. 1 illustrates a top plan view of a touch screen panel according to an exemplary embodiment.

FIGS. 2A and 2B illustrate a layout view and a cross-sectional view depicting a structure of a touch screen panel according to an exemplary embodiment.

FIGS. 3A and 3B illustrate a layout view and a cross-sectional view depicting a structure of a touch screen panel according to an exemplary embodiment.

FIGS. 4A, 5A, and 6A, and FIGS. 4B, 5B, and 6B illustrate top plan views and cross-sectional views for describing a method of manufacturing the touch screen panel according to the exemplary embodiment.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art.

In the drawing figures, the dimensions of layers and regions may be exaggerated for clarity of illustration. It will also be understood that when a layer or element is referred to as being “on” another layer or substrate, it can be directly on the other layer or substrate, or intervening layers may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present. Like reference numerals refer to like elements throughout.

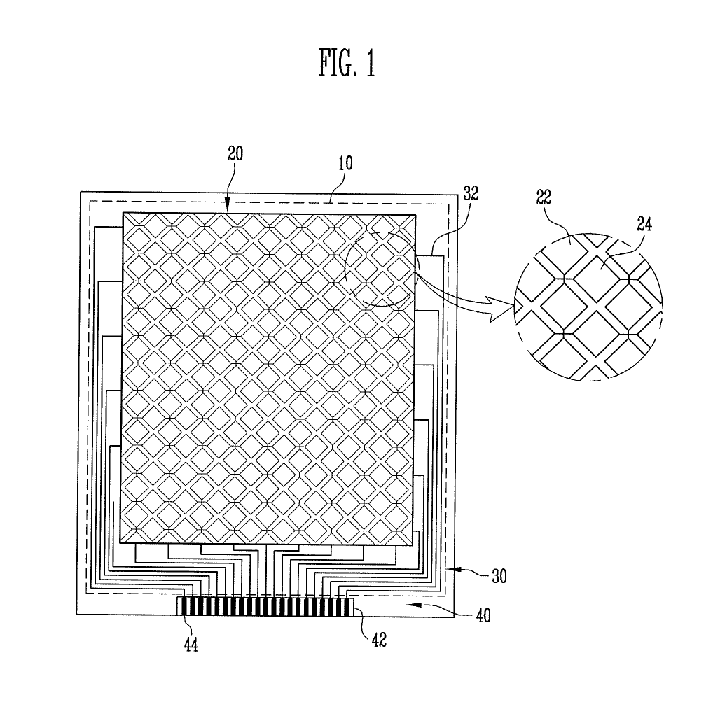

FIG. 1 is a top plan view of a touch screen panel according to an exemplary embodiment.

Referring to FIG. 1, a touch screen panel according to an exemplary embodiment may include a substrate 10, sensing electrodes 22 and 24, sensing lines 32 electrically connected with the sensing electrodes 22 and 24 and a pad part 42

The substrate 10 may include a touch active area 20 and touch non-active areas 30 and 40 defined at an outer portion of the touch active area 20. The touch active area 20 is an area that detects a touch position, The touch active area 20 may be a display area in which an image is displayed. The touch active area 20 may be an area overlapping pixels included in a display panel disposed under the touch screen panel. The touch non-active areas 30 and 40 may include a first touch non-active area 30 and a second touch non-active area 40 defined at an outer portion of the first touch non-active area 30. The first and second touch non-active areas 30 and 40 may be non-display areas in which an image is not displayed. The sensing electrodes 22 and 24 may be positioned in the touch active area 20, the sensing lines 32 may be positioned in the first touch non-active area 30, and the pad parts 42 may be positioned in the second touch non-active area 40.

The sensing electrodes 22 and 24 may include first sensing electrodes 22 and second sensing electrodes 24 alternately disposed with respect to each other. For example, the first sensing electrodes 22 may be arranged in columns in which X-coordinates thereof are substantially the same and may be electrically connected with each other. The second sensing electrodes 24 may be arranged in rows in which Y-coordinates thereof are substantially the same and may be electrically connected with each other. The first sensing electrodes 22 arranged in one column may be patterned in a mutually connected form or may be connected with each other by a separate connection pattern. Similarly, the second sensing electrodes 24 arranged in one row may be patterned in a mutually connected form or may be connected with each other by a separate connection pattern.

The first sensing electrodes 22 may be disposed on the same layer as or a different layer from that of the second sensing electrodes 24. When the first sensing electrodes 22 and the second sensing electrodes 24 are disposed on the different layers, an insulating layer may be interposed between the first sensing electrodes 22 and the second sensing electrodes 24. The respective sensing electrodes 22 and 24 may include a bar shape such that a separate connection pattern is not included. The sensing electrodes 22 and 24 may have various forms, such as a metal mesh structure, a circular structure, or a triangular bar structure.

The sensing lines 32 may be positioned in the first touch non-active area 30. The sensing lines 32 may be connected with the first and second sensing electrodes 22 and 24. The pad part 42 may be positioned in the second touch non-active area 40. The pad part 42 may include a plurality of pads 44. The plurality of pads 44 may be connected with respective ones of the plurality of sensing lines 32. The plurality of pads 44 may be connected with the first and second sensing electrodes 22 and 24 through the sensing lines 32. For example, the sensing lines 32 connected with the first sensing electrodes 22 may be connected with the pads 44 in one portion of the pad part 42, and the sensing lines 32 connected with the second sensing electrodes 22 may be distributed and arranged at a left side and a right side based on the touch active area 20 to be connected with the pads 44 arranged at a left side and a right side of the pad part 42. In the present exemplary embodiment, it is illustrated that the pad part 42 is positioned at the center of the second touch non-active area 40. In other implementations, the pad part 42 may be biasedly positioned at one side of the second touch non-active area 40.

According to the aforementioned structure, when a hand of a person or a touch object, such as a touch stick, is in contact with the touch screen panel, a change in capacitance according to a contact position may be transmitted to a driving circuit through the sensing electrodes 22 and 24, the sensing line 16, and the pad part 40. Further, the change in capacitance may be converted into an electric signal by an X and Y input processing circuit or the like, so that the contact position may be recognized.

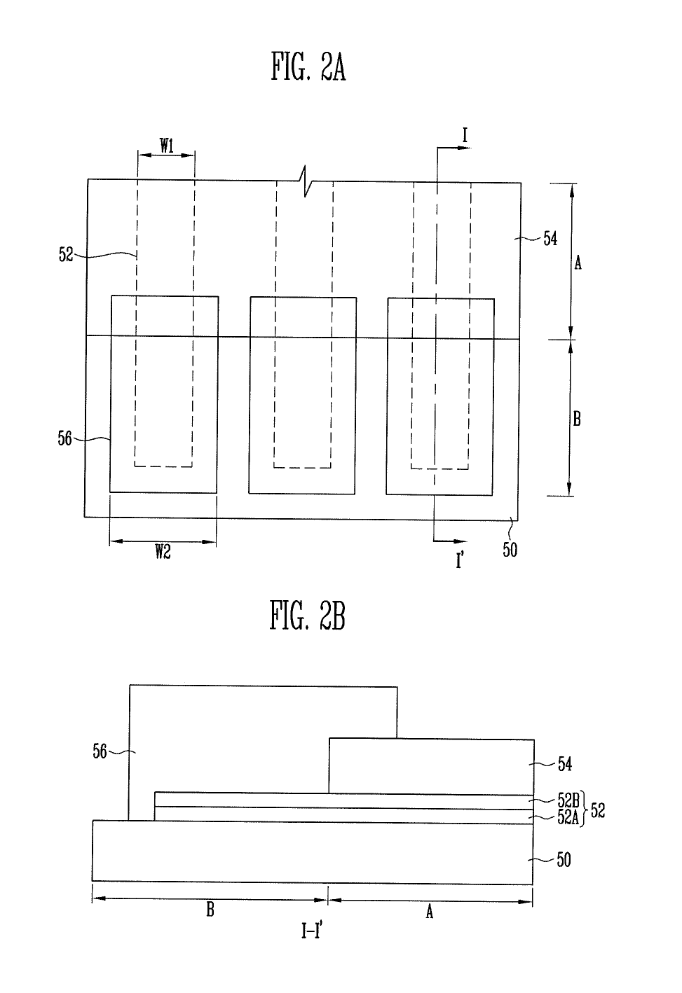

FIGS. 2A and 2B illustrate a layout view and a cross-sectional view depicting a structure of a touch screen panel according to an exemplary embodiment. FIG. 2B illustrates a cross-sectional view taken along line I-I′ of FIG. 2A.

Referring to FIGS. 2A and 2B, a touch screen panel according to an exemplary embodiment may include a substrate 50 including a first touch non-active area A and a second touch non-active area B, lines 52 positioned on the substrate 50, a passivation layer 54 that covers parts of the lines 52, and pads 56 electrically connected with the lines 52.

Each line 52 may be a sensing line connected with a sensing electrode arranged in a touch active area (see FIG. 1). The lines 52 may extend from the first touch non-active area A and the second touch non-active area B, and may include a metal layer 52A and a transparent conductive oxide layer 52B on the metal layer 52A. The metal layer 52A may have a nano structure, such as a nano wire, a nano tube, and a nano rod, and may include silver (Ag) or the like. Further, the transparent conductive oxide layer 52B may include an indium tin oxide (ITO), an indium zinc oxide (IZO), a zinc oxide (ZnO), an indium oxide (In₂O₃), an indium gallium oxide (IGO), an aluminum zinc oxide (AZO), or the like.

The passivation layer 54 may prevent the lines 52 from being corroded or damaged due to high temperature or moisture permeation according to the exposure of the lines 52. For example, the passivation layer 54 may prevent the metal layer 52A included in the line 52 from being damaged. The passivation layer 54 may have a form covering a part of the lined so that distal ends of the lined are exposed. For example, the passivation layer 54 may be positioned in the touch active area and the first touch non-active area A to cover the sensing electrode and the line 52. Further, the passivation layer 54 may be positioned in the first touch non-active area A to cover the lines 52. The passivation layer 54 may include an organic material or an inorganic material.

The pads 56 may be formed on and electrically connected with respective ones of the lines 52. Each pad 56 may be formed to cover a distal end of the respective line 52 exposed by the passivation layer 54, and may cover a part of the passivation layer 54. The pads 56 and the passivation layer 54 may partially overlap. As described above, when the pads 56 and the passivation layer 54 overlap, it may be possible to prevent the lines 52 from being exposed through a gap between the pads 56 and the passivation layer 54.

Further, each of the pads 56 may have a width W2 that is larger than a width W1 of the respective line 52 (W2 >W1). In this case, the pad 56 may an upper surface and a lateral wall of the line 52, such that it is possible to prevent the line 52 from being exposed and damaged. The pads 56 may include silver (Ag), palladium (Pd), or platinum (Pt).

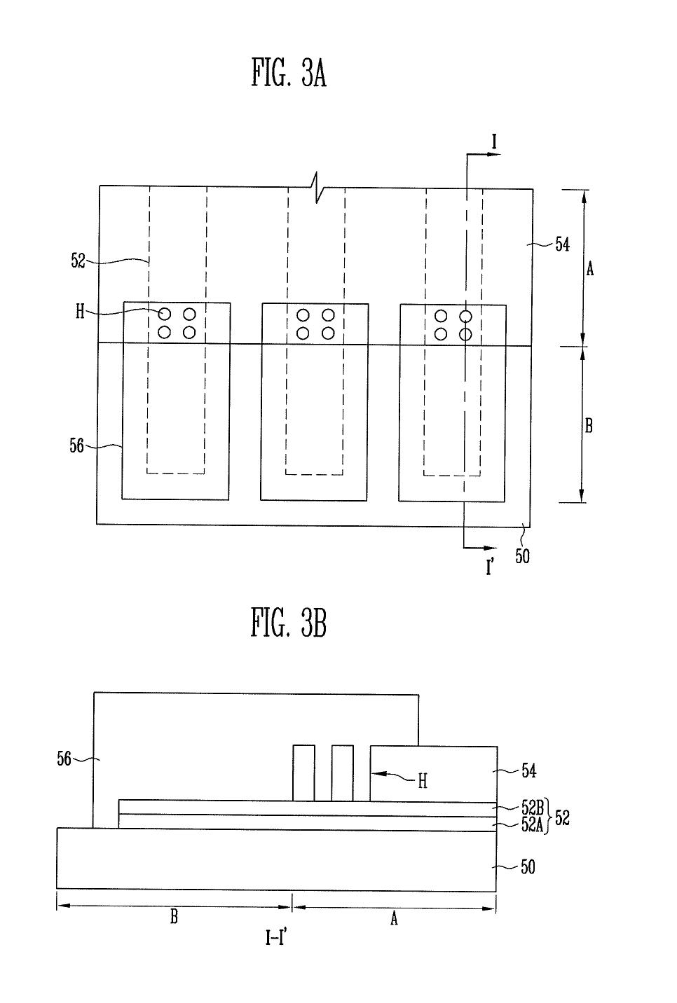

FIGS. 3A and 3B illustrate a layout view and a cross-sectional view depicting a structure of a touch screen panel according to an exemplary embodiment. FIG. 3B illustrates a cross-sectional view taken along line I-I′ of FIG. 3A. Hereinafter, content overlapping the aforementioned description will not be repeated.

Referring to FIGS. 3A and 3B, a touch screen panel according to an exemplary embodiment may include a substrate 50 including a first touch non-active area A and a second touch non-active area B, lines 52 positioned on the substrate 50, a passivation layer 54 for covering parts of the lines 52, and pads 56 electrically connected with the lines 52.

The passivation layer 54 may include one or more through-holes H exposing the lines 52. The pads 56 may partially overlap the passivation layer 54. Each pad 56 may formed to fill the one or more through-holes H corresponding to a respective one of the lines 52. Accordingly, the pads 56 may be electrically connected with respective ones of the lines 52 through the through-holes H.

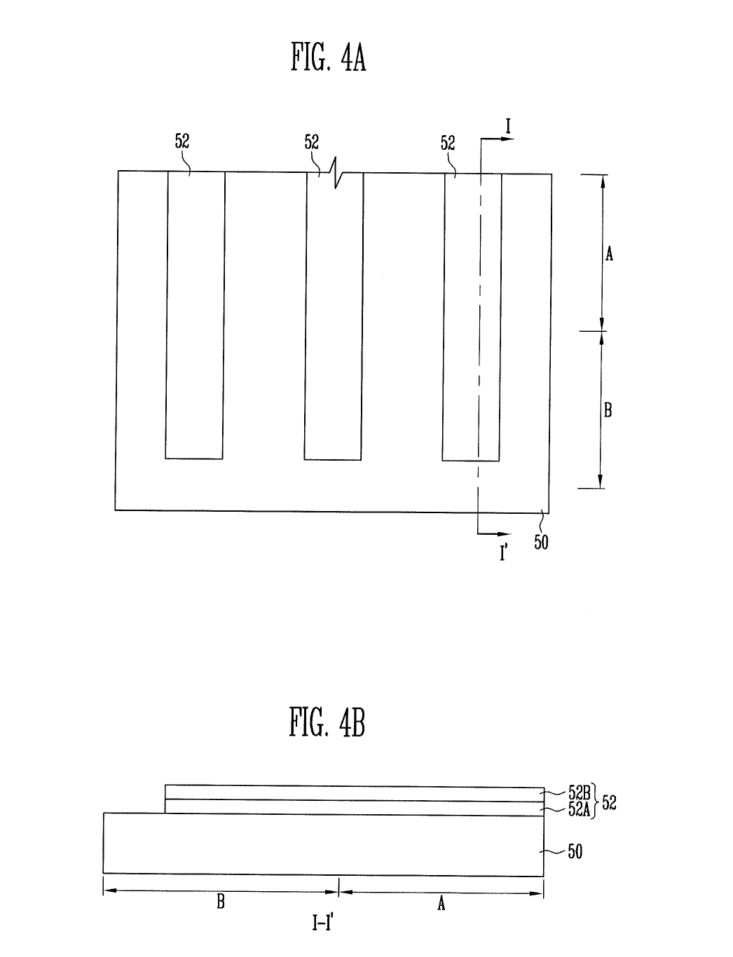

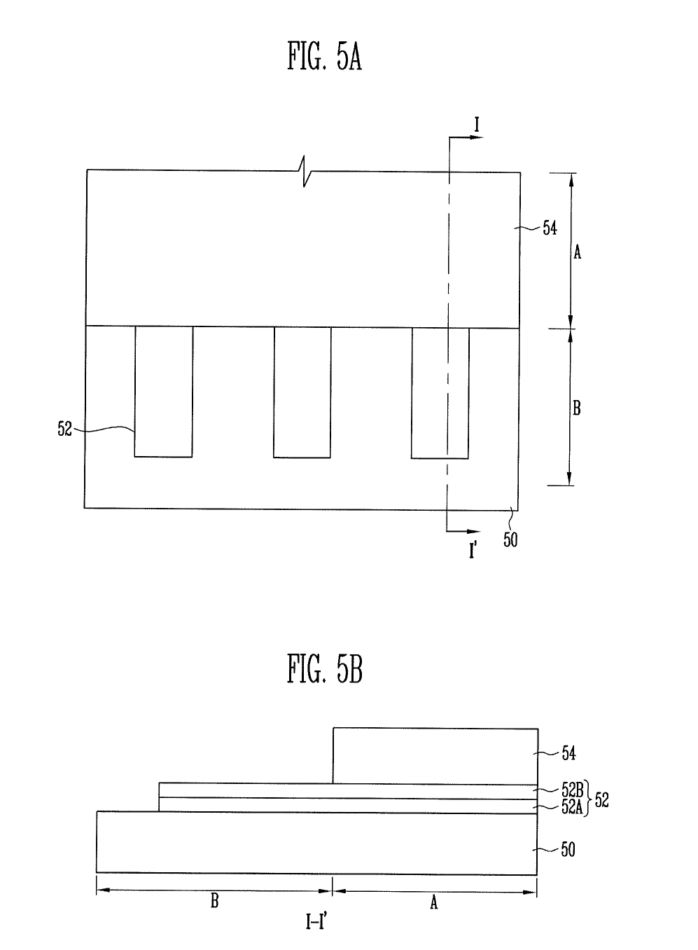

FIGS. 4A, 5A, and 6A, and FIGS. 4B, 5B, and 6B illustrate top plan views and cross-sectional views for describing stages of a method of manufacturing the touch screen panel according to the exemplary embodiment. FIGS. 4B, 5B, and 6B are cross-sectional views taken along line I-I′ of FIGS. 4A, 5A, and 5A.

Referring to FIGS. 4A and 4B, the lines 52 may be formed on the substrate 50. For example, the metal layer 52A and the transparent conductive oxide layer 52B may be formed on the substrate 50, and the lines 52 may be formed by patterning the metal layer 52A and the transparent conductive oxide layer 52B. The lines 52 may be positioned in the first touch non-active area A and the second touch non-active area B. When the lines 52 are formed, the sensing electrodes positioned in the touch active area may be formed together with the lines 52 (see FIG. 1). In this case, the sensing electrodes may include the metal layer and the transparent conductive oxide layer on the metal layer.

Referring to FIGS. 5A and 5B. the passivation layer 54 covering a part of the lines 52 may be formed on the substrate 50. The passivation layer 54 may be formed to cover a region of the lines 52 formed in the first touch non-active area A and may expose a region of the lines 52 formed in the second touch non-active area B. The passivation layer 54 may be formed to cover regions of the sensing electrode and the lines 52 formed in the touch active area and may expose regions of the sensing electrode and the lines 52 formed in the second touch non-active area B. Accordingly, a distal end of the lines 52 may be exposed.

After the passivation layer 54 is formed, the through-holes passing through the passivation layer 54 and exposing the lines 52 may be formed (see FIGS. 3A and 3B).

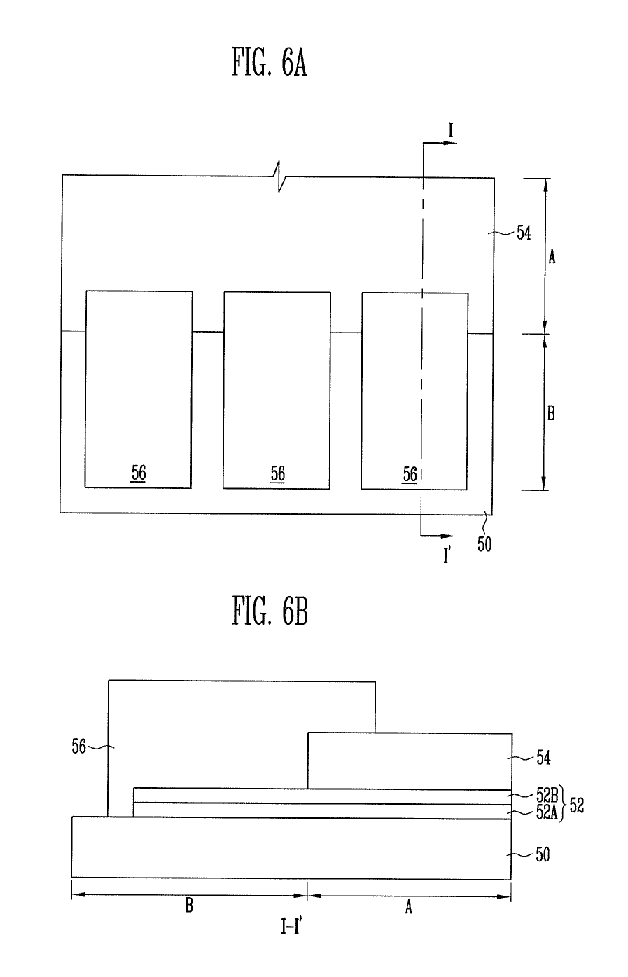

Referring to FIGS. 6A and 6B, the pads 56 electrically connected with the distal end of respective ones of the lines 52 is formed. The pads 56 may be formed in the second touch non-active area B or a part of the first touch non-active area A and the second touch non-active area B.

For example, a metal paste may be applied so as to be in contact with the lines 52 exposed by the passivation layer 54. The pads 56 may be formed by printing or patterning the metal paste. The metal paste may be formed to partially cover the passivation layer. The pads 56 and the passivation layer 54 may partially overlap. When the passivation layer 54 includes the through-holes, the metal paste may be formed to fill the through-holes.

According to the aforementioned process, the pads 56 may be formed by using the metal paste and the print process, such that the number of masks may be reduced, compared to a lithography process. Accordingly, it may be possible to decrease manufacturing cost.

By way of summation and review, a method of implementing a touch screen panel includes a resistive method, a light detection method, and a capacitive method. Among them, in the capacitive touch screen panel, when a hand of a person or an object touches the touch screen panel, a conductive sensing electrode detects a change in capacitance forming with another surrounding sensing electrode, a ground electrode, or the like to convert a contact position into an electric signal. Accordingly, the capacitive touch screen panel includes a sensing electrode, a sensing line, a pad, and the like which are electrically connected. When a pad of a touch screen panel has a structure in which a plurality of conductive layers is stacked, the pad may become corroded according to a material of the conductive layer.

The touch screen panel according to the exemplary embodiment includes a line in which a metal layer and a transparent conductive oxide layer are stacked, a passivation layer covering a part of the line, and a pad electrically connected with an exposed distal end of the line. Accordingly, it is possible to prevent the line from being corroded or damaged due to exposure. Further, the pad and the passivation partially overlap, such that it is possible to prevent the line from being exposed through a gap between the pad and the passivation layer.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated.

Accordingly, it will be understood by those of skill in the art that various changes in form and details may be made without departing from the spirit and scope thereof as set forth in the following claims.

What is claimed is:

1. A touch screen panel, comprising:
a substrate including a touch active area and a touch non-active area, the touch non-active area being defined at an outer portion of the touch active area;
lines located in the touch non-active area of the substrate, each of the lines including a metal layer including a nano structure and a transparent conductive oxide layer on the metal layer;
a passivation layer covering parts of the lines such that distal ends of the lines are exposed; and
pads electrically connected with the distal ends of the lines.

2. The touch screen panel as claimed in claim 1, wherein the pads partially cover the passivation layer.

3. The touch screen panel as claimed in claim 2, wherein:
the passivation layer includes one or more through-holes that expose the lines, and
the pads are electrically connected with the lines through the one or more through-holes.

4. The touch screen panel as claimed in claim 1, wherein each of the pads has a larger width than a respective one of the lines.

5. The touch screen panel as claimed in claim 1, wherein each of the pads is in contact with an upper surface and a lateral wall of the respective one of the lines.

6. The touch screen panel as claimed in claim 1, further comprising:
sensing electrodes located in the touch active area of the substrate, the sensing electrodes being connected with the lines.

7. The touch screen panel as claimed in claim 6, wherein each of the sensing electrodes includes a metal layer including a nano structure and a transparent conductive oxide layer on the metal layer.

8. The touch screen panel as claimed in claim 1, wherein the touch non-active area includes:
a first touch non-active area defined at the outer portion of the touch active area, the lines being located in the first touch non-active area; and
a second touch non-active area defined at an outer portion of the first touch non-active area, the pads being arranged in the second touch non-active area.

9. The touch screen panel as claimed in claim 8, wherein the passivation layer is located in the touch active area and the first touch non-active area.

10. The touch screen panel as claimed in claim 8, wherein the passivation layer is located in the first touch non-active area.

11. The touch screen panel as claimed in claim 1, wherein the metal layer includes a nano wire, a nano tube, or a nano rod structure.

12. The touch screen panel as claimed in claim 1, wherein each of the pads includes silver (Ag), palladium (Pd), or platinum (Pt).

13. A method of manufacturing a touch screen panel, the method comprising:
forming lines including a metal layer having a nano structure and a transparent conductive oxide layer on the metal layer, on a substrate;
forming a passivation layer covering parts of the lines such that distal ends of the line are exposed; and
forming pads electrically connected with the distal ends of the lines.

14. The method as claimed in claim 13, wherein forming the pads includes:
applying a metal paste to be in contact with the lines; and
forming the pads by printing the metal paste.

15. The method as claimed in claim 13, wherein each of the pads is formed to partially cover the passivation layer.

16. The method as claimed in claim 15, further comprising, before forming the pads:
forming one or more through-holes that pass through the passivation layer and expose the lines.

17. The method as claimed in claim 16, wherein forming the pads includes:
applying a metal paste so as to fill the one or more through-holes and be in contact with the lines; and
forming the pads by printing the metal paste.

18. The method as claimed in claim 13, wherein the substrate includes a touch active area, a first touch non-active area that is defined at the outer portion of the touch active area and in which the lines are arranged, and a second touch non-active area that is defined at an outer portion of the first touch non-active area and in which the pads are arranged.

19. The method as claimed in claim 18, wherein the passivation layer covers regions of the lines corresponding to the first touch non-active area, and exposes regions of the lines corresponding to the second touch non-active area.
